(19) United States
(12) Patent Application Publication
(10) Pub. No.: US 2012/0043570 A1
(43) Pub. Date: Feb. 23, 2012

(54) SEMICONDUCTOR DEVICE AND METHOD OF MANUFACTURING THE SAME

(75) Inventors: Hiroyuki Nakashima, Fukuoka-ken (JP); Yoshio Ariizumi, Fukuoka-ken (JP); Yoji Ishikawa, Fukuoka-ken (JP)

(73) Assignee: KABUSHIKI KAISHA TOSHIBA, Tokyo (JP)

(21) Appl. No.: 13/043,734

(22) Filed: Mar. 9, 2011

(30) Foreign Application Priority Data
Aug. 17, 2010 (JP) 2010-182228

(51) Int. Cl. H01L 33/58

(52) U.S. Cl. 257/98; 438/29; 257/E33.073

(57) ABSTRACT

According to one embodiment, a semiconductor device includes a lead, a frame, an optical semiconductor element, a sealing resin and a lens. The frame includes a main body covering a portion of the lead and being provided with a recess, another portion of the lead being exposed in the recess, and a casing part provided along an opening edge of the recess, the casing part including a cutout portion. The optical semiconductor element is provided in the recess and is in electrical connection with the lead. The sealing resin fills the recess from a bottom to the casing part, thereby covering the optical semiconductor element. The lens is joined to the sealing resin.

### CROSS-REFERENCE TO RELATED APPLICATIONS

This application is based upon and claims the benefit of priority from the prior Japanese Patent Application No. 2010-182228, filed on Aug. 17, 2010; the entire contents of which are incorporated herein by reference.

### FIELD

Embodiments of the invention relate generally to a semiconductor device and method for manufacturing the same.

### BACKGROUND

Semiconductor devices incorporating optical semiconductor elements, for example, semiconductor devices in which a high intensity Light Emitting Diode (LED) element is incorporated in a Surface Mount Device (SMD) package that is surface mountable on a printed circuit board, are used in various types of apparatuses.

Moreover, in order to effectively utilize the luminescent light of the LED, a lens is provided in a radiation direction of the light to improve directionality. For example, with an LED of an SMD-type, a molded lens using a transparent resin can be provided on a frame face that will become a reflection face of the luminescent light.

However, depending on conditions of the frame face, for example, depending on shape and unevenness, air may be trapped during molding, and air bubbles may be caught between the frame face and the lens. As a result, defects such as weakening of the bonding strength between the lens and the frame, and variations of the radiation pattern may occur. Therefore, semiconductor devices having a structure in which the generation of air bubbles between the frame face and the lens can be suppressed, and a method for manufacturing the same, are needed.

### BRIEF DESCRIPTION OF THE DRAWINGS

FIG. 1 is a schematic view illustrating a cross-section of a semiconductor device according to a first embodiment;

FIG. 2A to 5 are cross-sectional views schematically illustrating manufacturing processes of the semiconductor device according to the first embodiment;

FIGS. 6A and 6B are schematic views illustrating a semiconductor device according to a variation of the first embodiment.

FIG. 7A is a schematic perspective view illustrating a semiconductor device, and FIG. 7B is a schematic cross-sectional view illustrating an internal structure of the semiconductor device according to a second embodiment;

FIGS. 8A and 8B are schematic cross-sectional views illustrating a manufacturing process of the semiconductor device according to the second embodiment;

FIG. 9A is a schematic view illustrating a partial cross-section of the semiconductor device according to the second embodiment, and FIG. 9B is a schematic view illustrating a partial cross-section of a semiconductor device 250 according to a comparative example;

FIGS. 10A and 10B are schematic cross-sectional views illustrating a manufacturing process of the semiconductor device according to a variation of the second embodiment;

FIG. 11A is a perspective view illustrating a semiconductor device, and FIG. 11B is a cross-sectional view illustrating an internal structure of the semiconductor device according to another variation of the second embodiment; and

FIG. 12A is a perspective view of a lens according to a comparative example and FIG. 12B is a perspective view of a lens according to another variation of the second embodiment.

### DETAILED DESCRIPTION

In general, according to one embodiment, a semiconductor device includes a lead, a frame, an optical semiconductor element, a sealing resin and a lens. The frame includes a main body covering a portion of the lead and being provided with a recess, another portion of the lead being exposed in the recess, and a casing part provided along an opening edge of the recess, the casing part including a cutout portion. The optical semiconductor element is provided in the recess and is in electrical connection with the lead. The sealing resin fills the recess from a bottom to the casing part, thereby covering the optical semiconductor element. The lens is joined to the sealing resin.

Embodiments of the invention will now be described while referring to the drawings. Note that in the following embodiments, the same numerals are applied to constituents that have already appeared in the drawings and, and repetitious detailed descriptions of such constituents are appropriately omitted.

### First Embodiment

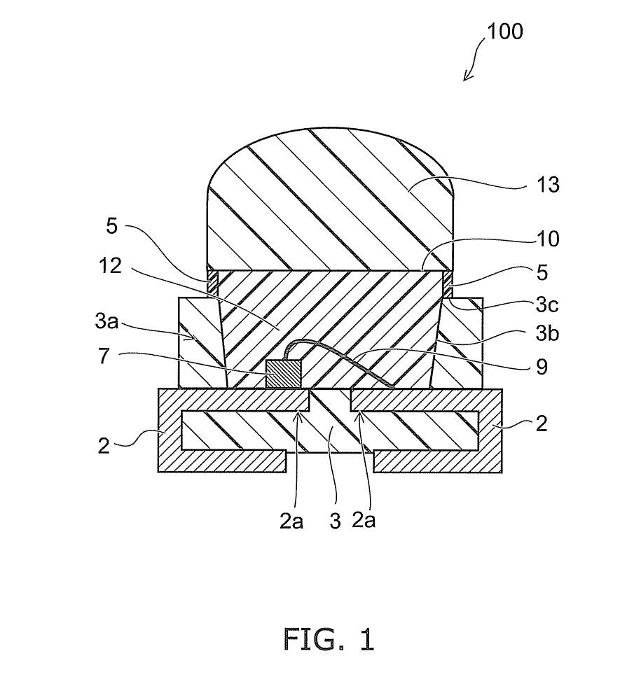

FIG. 1 is a schematic view illustrating a cross-section of a semiconductor device 100 according to a first embodiment.

The semiconductor device 100 is, for example, an LED device using a lead having a resin molded cup, and includes a lead 2 and a frame 3 provided so as to cover a portion of the lead 2.

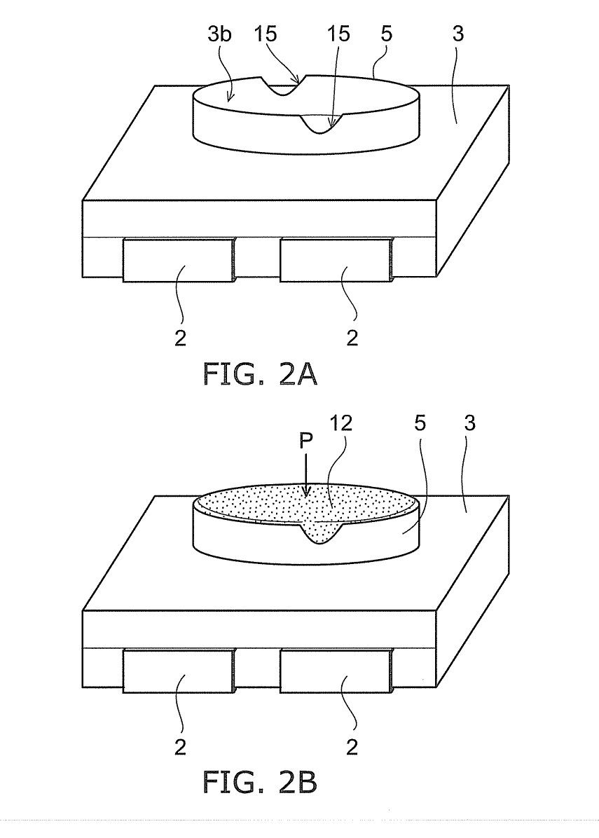

The frame 3 has a main body 3a and a casing part 5. A cup-like recess 3b is provided in the main body 3a and another portion 2a of the lead 2 is exposed at a bottom of the recess 3b. The casing part 5 is provided on an opening end 3c of the recess 3b of the main body 3a. A cutout portion 15 (see FIG. 2A) is provided in the casing part 5. The casing part 5 is arranged as a wall-like body surrounding the recess 3b. The cutout portion 15 is formed so as to cut into the casing part 5 from an edge of the casing part 5, which is formed as a wall-like body, toward a direction of the recess 3b. In other words, a height of the casing part 5 when viewed from the opening end 3c (in FIG. 1, the height in the vertical direction looking straight on) is lower in the cutout portion 15.

An LED chip 7, which is an optical semiconductor element in electrical connection with the lead 2, is disposed in an interior of the recess 3b.

For example, as illustrated in FIG. 1, the LED chip 7 is mounted on one of the two leads 2 exposed at the bottom of the recess 3b, and another of the leads 2 and the LED chip 7 are connected using a metal wire 9.

Then, from the bottom of the recess 3b to a height reaching the casing part 5 is filled with a sealing resin 12, thereby covering the LED chip 7. A surface 10 of the sealing resin 12 that the recess 3b is filled with is a frame face on which a lens will be provided. For example, a molded lens 13 is joined thereon.

A transparent resin that transmits luminescent light of the LED chip 7 is used, for example, for the sealing resin 12. Furthermore, the lens 13 can also be molded using a transparent resin that transmits the luminescent light of the LED chip 7. For example, a thermosetting epoxy resin, a silicone resin, or the like can be used.

On the other hand, the frame 3 can be formed by insert molding using a thermoplastic resin such as, for example, polyphthalamide (PPA) or the like. Furthermore, by mixing a powder such as potassium titanate or the like with the resin, the frame 3 can be formed so as to reflect the luminescent light of the LED chip 7.

Hereinafter, a method for manufacturing the semiconductor device 100 will be described while referring to FIGS. 2 to 5.

The method for manufacturing the semiconductor device 100 according to this embodiment includes processes of: filling from the bottom of the recess 3b formed on the main body 3a of the frame 3 to a height reaching the casing part 5 with the sealing resin 12, thereby covering the LED chip 7 that is an optical semiconductor element; and hardening the sealing resin 12. While the hardening process, a portion of the sealing resin 12 flows out from the cutout portion 15, thereby forming an indentation 12a on an inner side of the casing part 5 that corresponds with the cutout portion 15. Furthermore, the method includes a process of molding the lens 13 on the sealing resin 12.

As illustrated in FIG. 2A, the frame 3 includes the casing part 5 of the wall-like body arranged on the opening end 3c (see FIG. 1) of the cup-like recess 3b so as to surround the recess 3b. The cutout portion 15 is provided in the casing part 5 from the edge thereof in the direction of the recess 3b.

First, the LED chip 7 is disposed at the bottom of the recess 3b (see FIG. 1). Then, from the bottom of the recess 3b to a top of the casing part 5 is filled with the sealing resin 12. Thereafter, heat treating is performed to harden the sealing resin 12, thus sealing the LED chip 7.

FIG. 2B illustrates the frame after filling with the sealing resin 12. Here, the sealing resin 12 is a liquid having viscosity, prior to hardening by being subjected to heat treating.

For example, when using a thermosetting epoxy resin for the sealing resin 12, the epoxy resin will have adequate viscosity. Therefore, after filling, the epoxy resin will not spill out from the cutout portion 15, that is lower than other portion of the casing part 5, to an outside of the casing part 5.

Next, after the heat treating and the hardening of the sealing resin 12, the lens 13 is formed on the sealing resin 12. At this time, it is preferable that a center P of the sealing resin 12 bulges, having a convex shape. If the center P of the sealing resin 12 has an indented concave shape after hardening, air will be trapped when forming the lens 13 and air bubbles will easily form between the sealing resin 12 and the lens 13.

In other words, if a filling amount of the sealing resin 12 is insufficient, the resin surface will become concave shaped due to the contracting action while thermosetting. On the other hand, if the amount of the sealing resin 12 is increased, it is possible to fill to a state in which the center P of the sealing resin 12 bulges due to the viscosity of the resin. However, the resin will spill over to the outside of the casing part 5 due to a temporary decrease in viscosity in the thermosetting process. Therefore, the surface may not become convex shaped. The shape of the sealing resin 12 after hardening is dependent on the degree to which the recess 3b and the interior of the casing part 5 are filled. Therefore, the filling amount must be precisely controlled. This results in a challenging problem of forming the surface of the sealing resin 12 that fills the interior of the casing part 5 into a stable convex shape.

In the semiconductor device 100 according to this embodiment the cutout portion 15 is provided in the casing part 5. Hereinafter, the function of the cutout portion 15 will be described.

As illustrated in FIG. 2B, after filling the interior of the recess 3b with the sealing resin 12, heat treatment is performed and the sealing resin 12 is hardened.

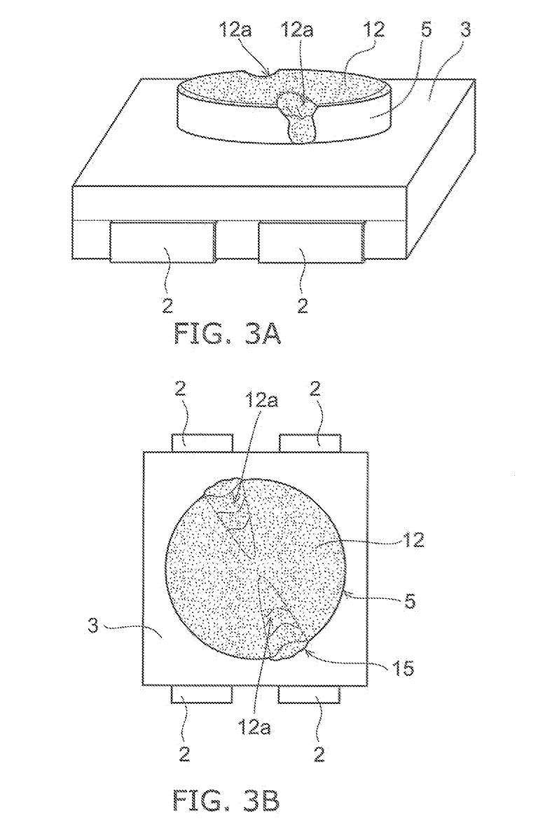

For example, when using a thermosetting resin, in this process, the viscosity of the sealing resin 12 temporarily decreases and, thereafter, the resin is hardened. At this time, a portion of the sealing resin 12 having decreased viscosity spills out from the cutout portion 15, which is lower than the other portion of the casing part 5, to the outside of the casing part 5. As schematically illustrated in FIG. 3A, the indentation 12a corresponding to the cutout portion 15 is formed in the surface of the sealing resin 12 hardened in the interior of the casing part 5.

A shape and a depth of the indentation 12a formed in the surface of the sealing resin 12 is dependent on a shape and a size of the cutout portion 15 and, furthermore, on the properties of the sealing resin. For example, as illustrated in FIG. 3B, the indentation 12a can be formed into a groove shape continuing from the interior of the casing part 5 to the cutout portion 15.

For example, if a width (in a direction along an edge of the casing part 5) of the cutout portion 15 is increased, an area of the indentation 12a will increase. Alternatively, if the width of the cutout portion 15 is made relatively smaller and the cutout portion 15 is formed with an increased depth in the direction of the recess 3b, then it will be possible to form the indentation 12a having a groove shape.

The cutout portion 15 illustrated in FIGS. 2A and 2B and FIGS. 3A and 3B is formed of a cup-like shape in the direction of the recess 3b, but may also be formed of a rectangular shape.

Next, the lens 13 is formed on the sealing resin 12.

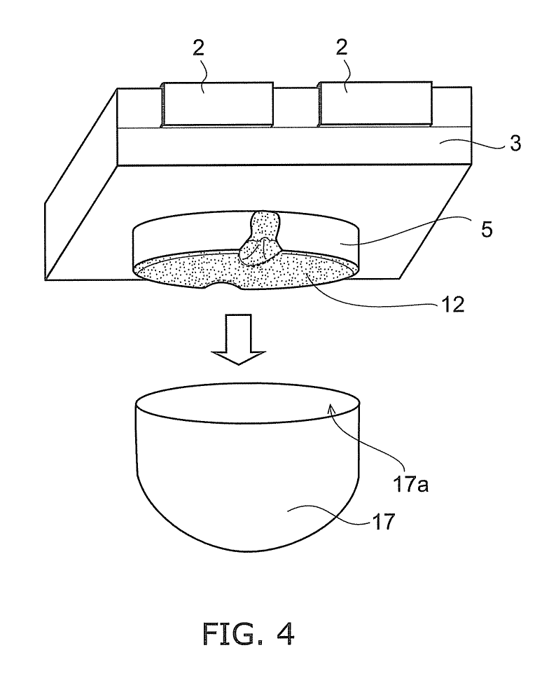

For example, as illustrated in FIG. 4, the frame 3 filled with the sealing resin 12 is engaged with a mold 17 that is filled with a resin that will become the lens 13. An interior of the mold 17 is processed into a shape of the lens 13.

As illustrated in the same drawing, by engaging (or inserting) the casing part 5 with (or into) an opening 17a of the mold 17, the surface of the sealing resin 12 and the resin that the interior of the mold 17 has been filled with can be joined.

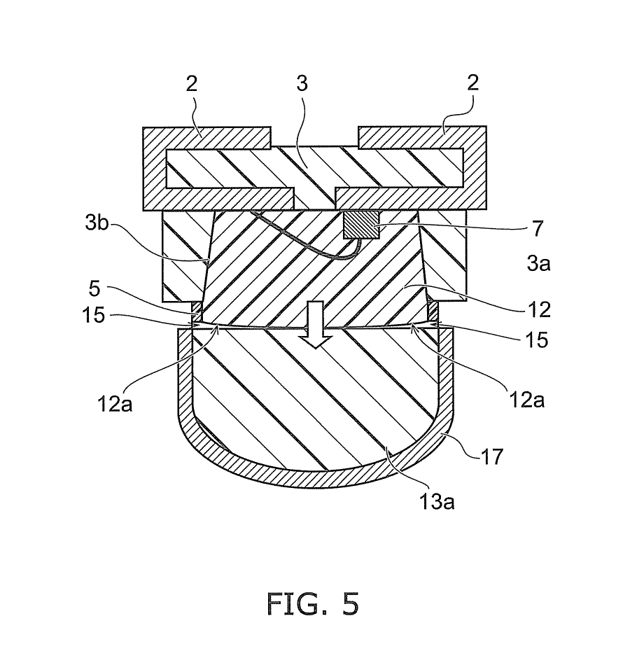

FIG. 5 is a cross-sectional view schematically illustrating a state in which the casing part 5 of the frame 3 and the mold 17 are engaged.

As previously described, the indentation 12a is provided in the surface of the sealing resin 12 that the interior of the recess 3b is filled with. The indentation 12a is formed, for example, into a groove shape connected to the cutout portion 15. Thus, when a resin 13a that the mold 17 is filled with is engaged with the surface of the sealing resin 12, air remaining between the sealing resin 12 and the resin 13a can be released from the cutout portion 15 to the outside via the indentation 12a.

Thereby, for example, even if the amount of the sealing resin 12 that the recess 3b is filled with is insufficient, air will not remain between the sealing resin 12 and the resin 13a that will become the lens 13. Therefore, the generation of air bubbles between the lens 13 and the sealing resin 12 can be suppressed.

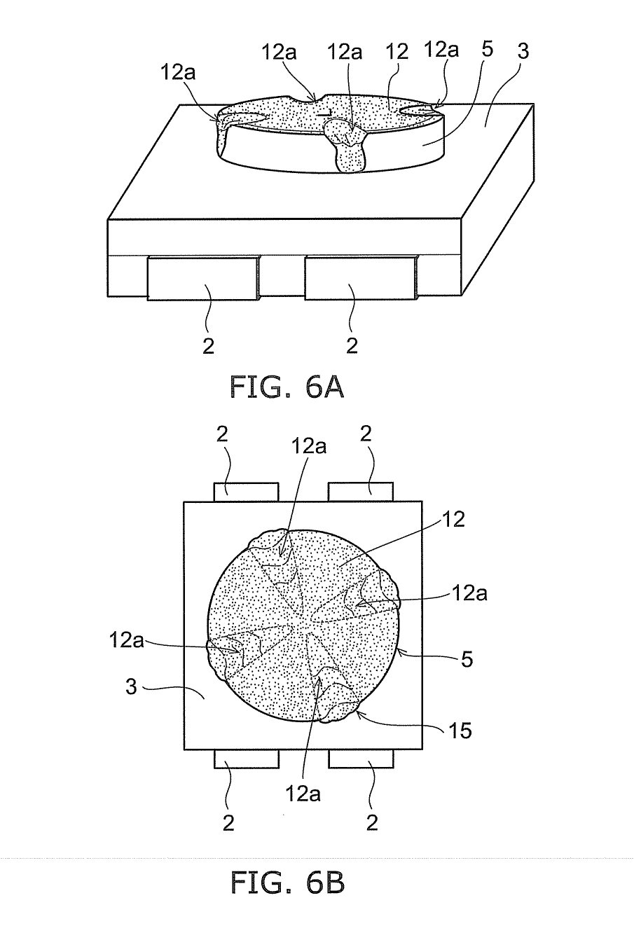

Furthermore, as illustrated in FIGS. 6A and 6B, the number of the cutout portions 15 may be increased.

FIG. 6A is a perspective view schematically illustrating a state in which the heat treatment has been performed and the sealing resin 12 has been hardened after filling from the bottom of the recess 3b to the top of the casing part 5 with the sealing resin 12. FIG. 6B is a plan view thereof.

In an example illustrated in FIGS. 6A and 6B, four of the cutout portions 15 are provided in the casing part 5. The sealing resin 12 spills from each of the cutout portions 15 to the outside of the casing part 5 and four of the indentations 12a are formed. Thereby, air remaining between the sealing resin 12 and the resin 13a that will become the lens 13 can be assuredly released to the outside and the generation of air bubbles can be suppressed.

The number of the cutout portions 15 provided in the casing part 5 is not limited to two or four as described above in this embodiment. The number of the cutout portions 15 can be determined as desired based on the frame 3 and the size of the recess 3b and the casing part 5. For example, one of the cutout portions 15 may be provided or the number of the cutout portions 15 may be increased to three to five or six.

### Second Embodiment

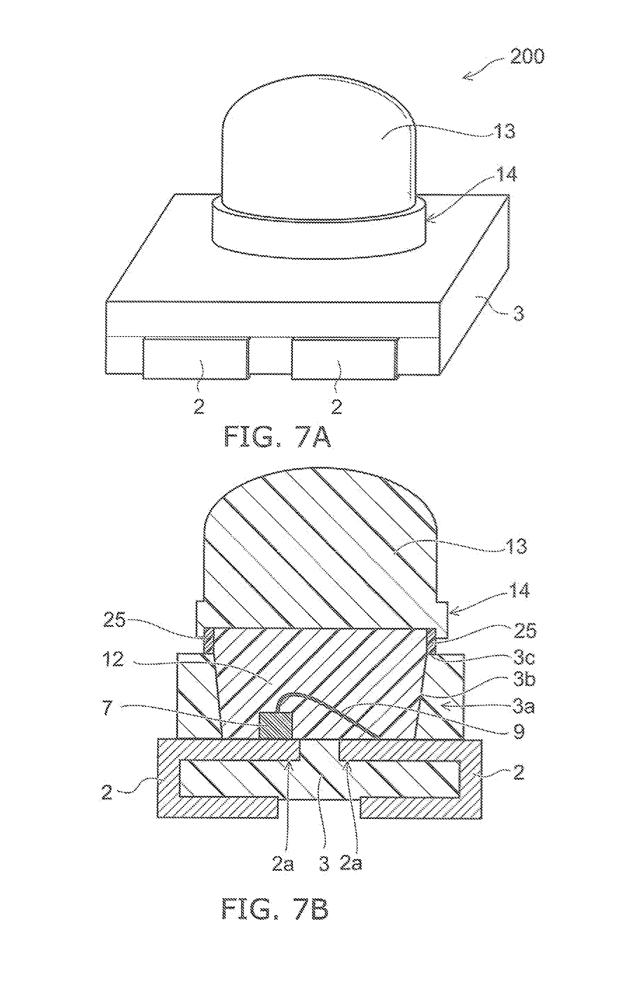

FIGS. 7A and 7B are schematic views illustrating a semiconductor device 200 according to a second embodiment. FIG. 7A is a perspective view illustrating a form of the semiconductor device 200. FIG. 7B is a cross-sectional view illustrating an internal structure.

As with the semiconductor device 100 illustrated in FIG. 1, the semiconductor device 200 according to this embodiment also includes a lead 2 and a frame 3 provided so as to cover a portion of the lead 2. As illustrated in FIG. 7A, a lens 13 is provided on the frame 3. A flange portion 14 is provided at a bottom of the lens 13 that is in contact with the frame 3.

As illustrated in FIG. 7B, the frame 3 includes a main body 3a and a casing part 25. A recess 3b in which another portion 2a of the lead 2 is exposed is provided in the main body 3a. The casing part 25 that is a wall-like body is arranged on an opening end 3c of the recess 3b. In this embodiment, a point of difference with the semiconductor device 100 according to the first embodiment is that a cutout portion 15 is not formed in the casing part 25.

An LED chip 7, which is an optical semiconductor element in electrical connection with the lead 2, is disposed in the recess 3b. Then, from the bottom of the recess 3b to a height reaching a top of the casing part 25 is filled with a sealing resin 12, thereby covering the LED chip 7.

A lens 13 is provided on the sealing resin 12 that the recess 3b is filled with. The lens 13 includes the flange portion 14 formed along a periphery of the casing part 25.

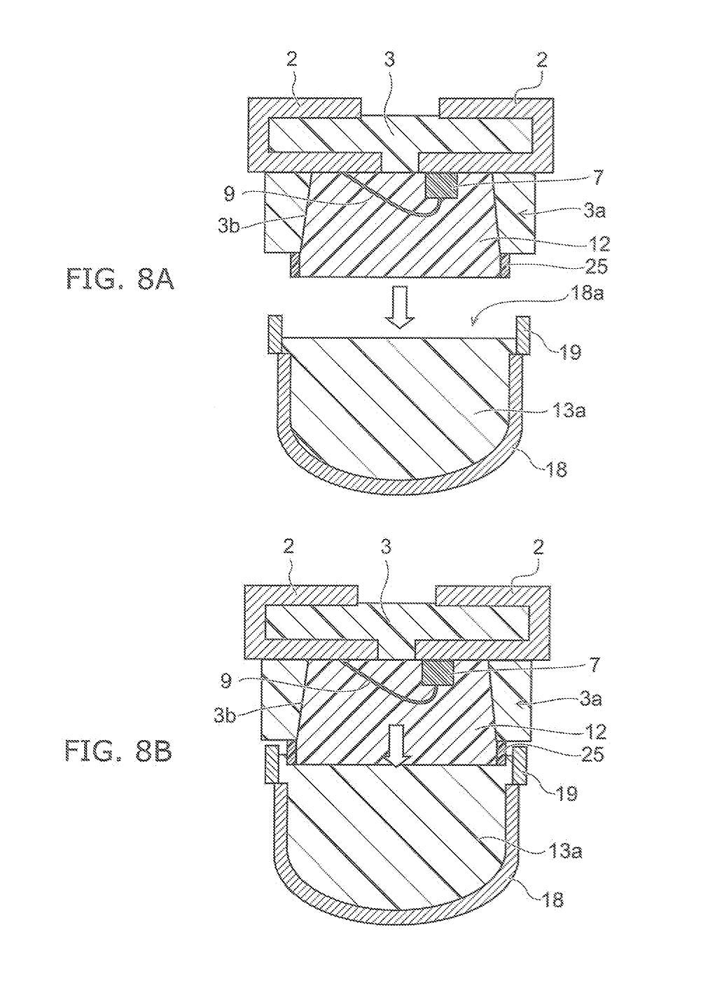

Next, a method for manufacturing the semiconductor device 200 will be described while referring to FIGS. 8A and 8B. FIG. 8A is a schematic cross-sectional view illustrating a state prior to the frame 3 filled with the sealing resin 12 being engaged with a mold 18. FIG. 8B is a schematic cross-sectional view illustrating a state in which the frame 3 is engaged with the mold 18.

The method for manufacturing the semiconductor device 200 also includes a process of filling from the bottom of the recess 3b to a height reaching the casing part 25 with the sealing resin 12, thereby covering the LED chip 7 that is an optical semiconductor element.

As illustrated in FIG. 8A, when engaging the frame 3 and the mold 18, the frame 3 side is filled with an excess of the sealing resin 12 to prevent air bubbles from being generated due to air becoming trapped between the resin 13a that will become the lens 13 and the sealing resin 12. On the other hand, the mold 18 is also filled with an extra amount of the resin 13a so that air bubbles are not generated due to an insufficient amount of the resin 13a.

Furthermore, in this embodiment, an inner surface of the mold 18 is processed into a shape of the lens 13, and a flange portion 19, which has an expanded inner diameter, is provided around an opening 18a.

As illustrated in FIG. 8B, when the frame 3 is engaged with the mold 18, the casing part 25 of the frame 3 engages by being inserted into the inner side of the flange portion 19.

The resin 13a that the interior of the mold 18 is filled with is joined with the surface of the sealing resin 12, and the lens 13 is formed. Here, a liquid level of the resin 13a that the interior of the mold 18 is filled with is pushed up, and the resin 13a is hardened at a height reaching the flange portion 19. The excess resin 13a fills in a gap between the flange portion 19 and the casing part 25, and the flange portion 14 of the lens 13 is formed along the periphery so as to surround the casing part 25.

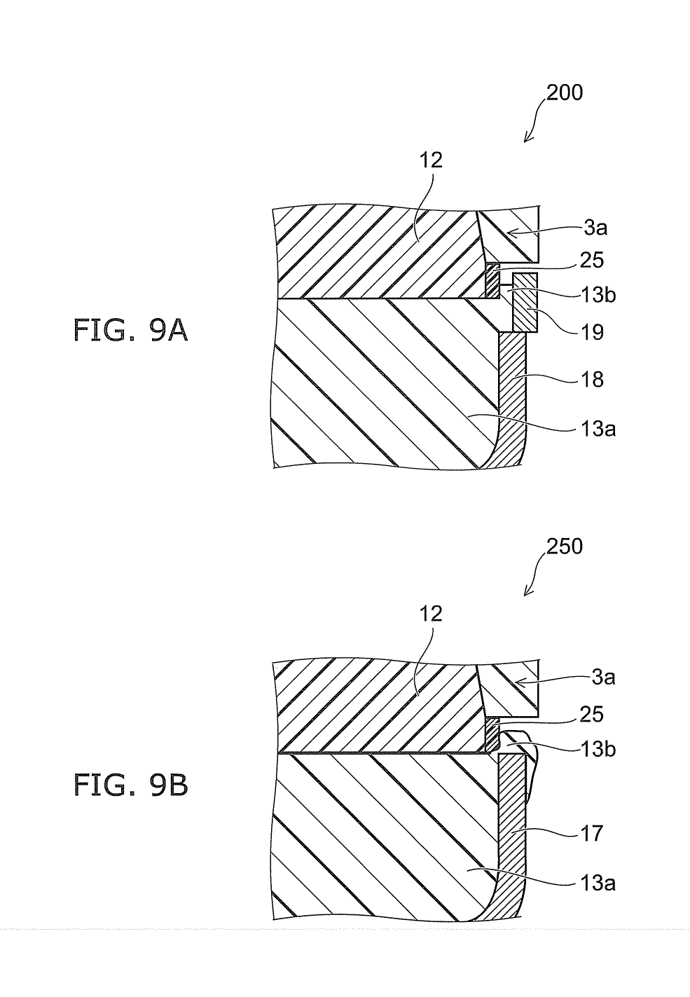

FIGS. 9A and 9B are schematic views illustrating partial cross-sections of the semiconductor device 200 and a semiconductor device 250 according to a comparative example, respectively.

As illustrated in FIG. 9A, in the semiconductor device 200, the excess resin 13b is contained in the gap between the flange portion 19 formed on the mold 18 and the casing part 25 of the frame 3, and can be formed into the flange portion 14 of the lens 13.

In contrast, in the semiconductor device 250 according to the comparative example illustrated in FIG. 9B, the opening 17a of the mold 17 not provided with the flange portion 19 is engaged with the casing part 25. In this case, because there is no space to contain the excess resin, the liquid level of the resin that the mold 17 is filled with rises, and the excess of the resin 13b spills out to the outside of the casing part 25. Then, the resin 13b is hardened around the lens 13 which leads to burrs being formed, which is a factor contributing to the generation of visual appearance defects.

Therefore, with the method for manufacturing according to this embodiment, by using the mold 18 that has the flange portion 19, the excess resin is formed into the flange portion 14 of the lens 13, and the generation of burrs on the lens 13 can be suppressed. Thereby, visual appearance defects caused by variations in the filling amount of the sealing resin 12 and the filling amount of the resin 13a that will become the lens 13 can be prevented.

For example, even if the filling amounts of the sealing resin 12 and the resin 13a are increased so that air bubbles are not generated at an interface between the lens 13 and the sealing resin 12, the excess resin 13b is formed into the flange portion 14 of the lens 13. Therefore, the generation of burrs can be suppressed.

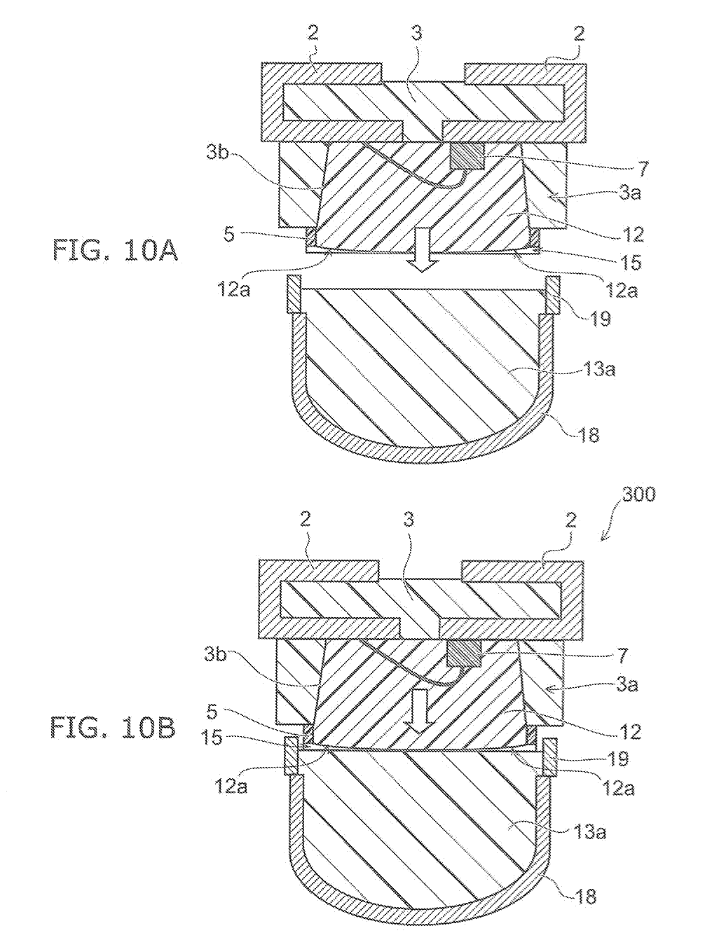

FIGS. 10A and 10B are cross-sectional views schematically illustrating a manufacturing process for a semiconductor device 300 according to a variation of the second embodiment. FIG. 10A illustrates a state prior to the frame 3 filled with the sealing resin 12 being engaged with the mold 18. FIG. 10B illustrates a state in which the frame 3 is engaged with the mold 18.

As illustrated in FIG. 10A, in the semiconductor device 300 according to this variation, just as with the semiconductor device 100, a cutout portion 15 is provided in the casing part 5 that is provided on the opening end 3c of the recess 3b of the frame 3. An indentation 12a is formed in a surface of the sealing resin 12 that the interior of the recess 3b is filled with.

As illustrated in FIG. 10B, when engaging the frame 3 and the mold 18 and joining the sealing resin 12 and the resin 13a that will become the lens 13, air can be released to the outside via the indentation 12a in the sealing resin 12. Furthermore, due to the flange portion 19 provided on the mold 18, spilling of the excess of the resin 13a to the outside can be suppressed. Thereby, the generation of air bubbles at the interface between the sealing resin 12 and the lens 13 can be suppressed, and the generation of burrs on the lens 13 can also be suppressed.

For example, compared to the semiconductor device 100 that does not have the flange portion 14, the filling amount of the sealing resin 12 and the filling amount of the resin 13a that the mold 18 will be filled with can be increased. On the other hand, compared to the semiconductor device 200 that does not have the cutout portion 15, even if the filling amounts of the sealing resin 12 and the resin 13a are small, the generation of air bubbles at the interface between the sealing resin 12 and the lens 13 can be suppressed. As a result, with the semiconductor device 300 according to this variation, the allowable range of the filling amounts of the sealing resin 12 and the resin 13a can be widened.

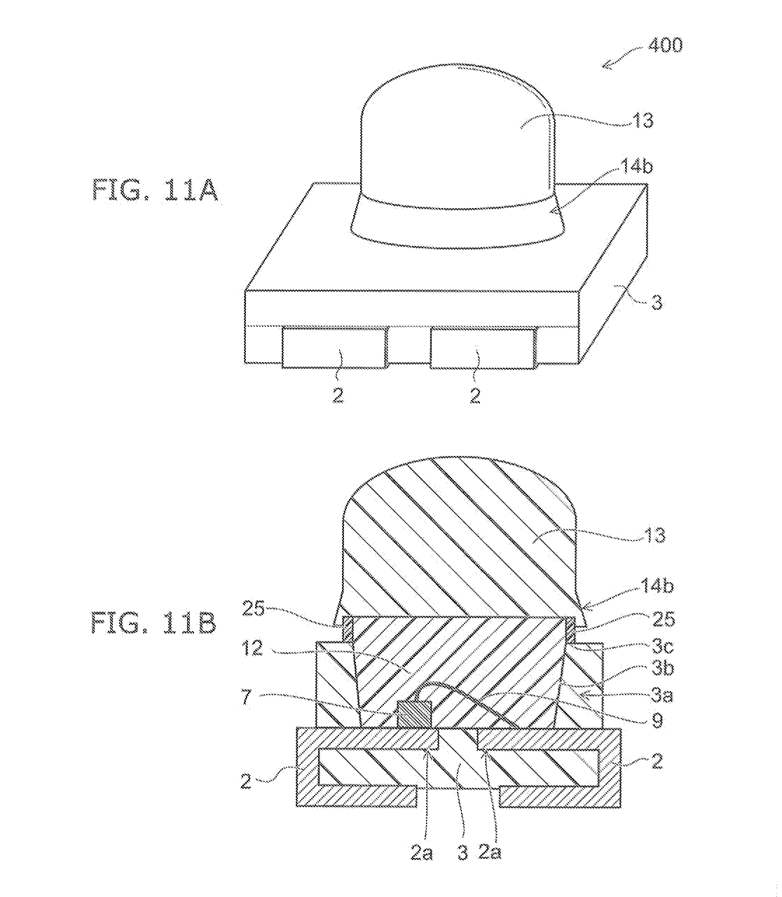

FIGS. 11A and 11B are schematic views illustrating a semiconductor device 400 according to a variation of the second embodiment. FIG. 11A is a perspective view illustrating a form of the semiconductor device 400. FIG. 11B is a cross-sectional view illustrating an internal structure of the semiconductor device 400.

As illustrated in FIG. 11A, the semiconductor device 400 includes a lead 2, a frame 3 provided covering a portion of the lead 2, and a lens 13 provided on the frame 3. The lens 13 has a flange portion 14b on a bottom of a side contacting the frame 3.

In the semiconductor device 400 according to this variation, it is different from the semiconductor device 200 illustrated in FIG. 7A in that the flange portion 14b is tapered so as to expand towards the frame 3.

As illustrated in the cross-section of FIG. 11B, the frame 3 and the internal structure thereof are the same as in the semiconductor device 200. The only difference is the shape of the flange portion 14b provided on the lens 13. Therefore, a shape of the flange portion 19 of the mold 18 that molds the lens 13 is different and has a shape that expands angularly in the direction of the opening 18a (see FIGS. 8A and 8B).

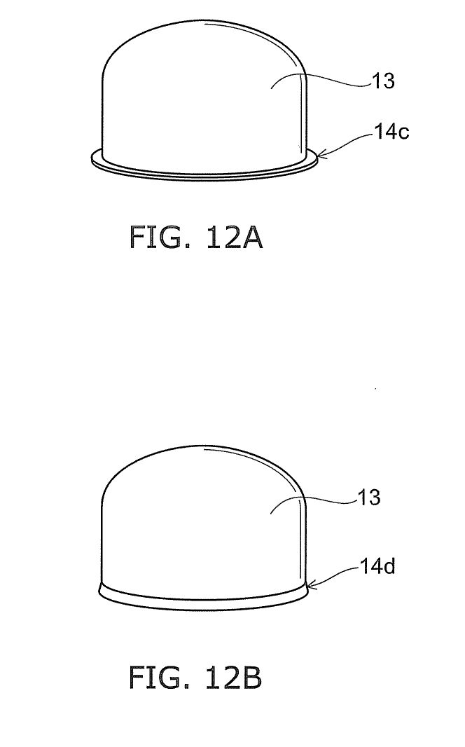

FIG. 12 A is a perspective view illustrating a shape of the lens 13 according to a comparative example and FIG. 12B is a perspective view illustrating a shape of the lens 13 according to the variation of the second embodiment.

FIG. 12A illustrates an example of the lens 13 according to the semiconductor device 200. In the example illustrated in the same drawing, the filling amount of the resin 13a that forms the lens 13 is small, and a formed flange portion 14c is thin. Thus, when the formed flange portion 14c is thin, there is a risk that the flange portion 14c may peel away from the lens 13, which is a factor, as with burrs, that may contribute to the generation of visual appearance defects.

FIG. 12B illustrates an example of the lens 13 according to the semiconductor device 400. In this case, because a flange portion 14d is tapered, even if the filling amount of the resin 13a is insufficient, only a width of the flange portion 14d in a tapering direction will be formed with a reduced width. Therefore, burrs will not be formed as with the flange portion 14c, and the insufficient filling amount will not contribute to the generation of visual appearance defects. As with the semiconductor device 400, there are instances in which it is advantageous to form the flange portion 14b with a tapered shape.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the invention.

What is claimed is:

1. A semiconductor device comprising:
a lead;
a frame including a main body covering a portion of the lead and being provided with a recess, an another portion of the lead being exposed in the recess, and a casing part provided along an opening edge of the recess, the casing part including a cutout portion;
an optical semiconductor element provided in the recess and being in electrical connection with the lead;
a sealing resin filling the recess from a bottom to the casing part, thereby covering the optical semiconductor element; and
a lens joined to the sealing resin.

2. The device according to claim 1, wherein the lens has a flange portion covering around the casing part.

3. The device according to claim 2, wherein the flange portion is tapered and expanding toward the frame.

4. The device according to claim 1, wherein the lens is a resin molded lens provided on the sealing resin filling the frame.

5. The device according to claim 1, wherein the sealing resin is a thermosetting resin transmitting light emitted from optical semiconductor element.

6. The device according to claim 5, wherein the sealing resin is one of an epoxy resin and a silicone resin.

7. The device according to claim 1, wherein the optical semiconductor element is a Light Emitting Diode (LED).

8. A semiconductor device comprising:
a lead;
a frame including a main body covering a portion of the lead and being provided with a recess, an another portion of the lead being exposed in the recess, and a casing part provided around an opening edge of the recess;
an optical semiconductor element provided in the recess and being in electrical connection with the lead;
a sealing resin filling the recess from a bottom to the casing part and covering the optical semiconductor element; and
a lens including a flange portion covering around the casing part and being joined to the sealing resin.

9. The device according to claim 8, wherein a cutout portion is provided in the casing part.

10. The device according to claim 8, wherein the flange portion is tapered and expanding toward the frame.

11. The device according to claim 8, wherein the lens is a resin molded lens provided on the sealing resin filling the frame.

12. The device according to claim 8, wherein the sealing resin is a thermosetting resin transmitting light emitted from optical semiconductor element.

13. The device according to claim 12, wherein the sealing resin is one of an epoxy resin and a silicone resin.

14. The device according to claim 8, wherein the optical semiconductor element is a Light Emitting Diode (LED).

15. A method for manufacturing a semiconductor device including a lead, a frame including a main body covering a portion of the lead and being provided with a recess, an another portion of the lead being exposed in the recess, and a casing part provided around an opening edge of the recess, the casing part including a cutout portion, and an optical semiconductor element provided in the recess and being in electrical connection with the lead, comprising the processes of:
filling from a bottom of the recess to a height reaching the casing part with a sealing resin, thereby covering the optical semiconductor element with the resin;
hardening the sealing resin after causing a portion of the sealing resin to flow out from the cutout portion, and forming an indentation corresponding with the cutout portion in a surface of the sealing resin on an inner side of the casing part; and
molding a lens joined to the surface of the sealing resin.

16. The method according to claim 15, wherein the sealing resin is a thermosetting resin transmitting light emitted from optical semiconductor element.

17. The method according to claim 15, wherein the sealing resin is a liquid and has a viscosity such that the sealing resin is held inside the frame and does not flow out from the cutout portion prior to the hardening.

18. The method according to claim 17, wherein the viscosity is lowered and the sealing resin is caused to flow out from the cutout portion by heating the sealing resin.

19. The method according to claim 15, wherein the process of molding the lens includes processes of filling an interior portion of a lens-shaped mold having a flange portion with a resin, the flange portion engaging with the casing part; and hardening the resin while a liquid level of the resin reaching the flange portion after engaging the casing part with the flange portion.

20. The method according to claim 19, wherein the mold has a shape angularly expanding in a direction of an opening.
